(19) United States
(12) Patent Application Publication
(10) Pub. No.: US 2025/0151622 A1
(43) Pub. Date: May 8, 2025

(54) SENSING SUBSTRATE, SENSING DEVICE AND MANUFACTURING METHOD THEREOF

(71) Applicant: InnoLux Corporation, Miao-Li County (TW)

(72) Inventors: Yu-Tsung LIU, Miao-Li County (TW); I-An YAO, Miao-Li County (TW)

(21) Appl. No.: 18/910,717

(22) Filed: Oct. 9, 2024

(30) Foreign Application Priority Data
Nov. 8, 2023 (CN) 202311480316.0

(51) Int. Cl. H10N 19/00

(52) U.S. Cl. CPC H10N 19/00

(57) ABSTRACT

A sensing substrate is provided. The sensing substrate includes a first substrate, a circuit layer, a planarization layer, a sensing unit and a first bonding layer. The circuit layer is disposed on the first substrate. The planarization layer is disposed on the circuit layer, and the planarization layer includes an opening. The sensing unit is disposed on the planarization layer, and the sensing unit is electrically connected to the circuit layer through the opening. The first bonding layer is disposed on the planarization layer.

### CROSS REFERENCE TO RELATED APPLICATIONS

This application claims the benefit of China Application No. 202311480316.0, filed Nov. 8, 2023, the entirety of which is incorporated by reference herein.

### BACKGROUND

### Technical Field

The present disclosure is related to a sensing substrate, a sensing device and a method of manufacturing the same.

### Description of the Related Art

Sensing devices are widely used in various electronic products and have become an indispensable necessity in modern society. With the development of automation technology, the frequency of use of sensing devices has grown rapidly, and most modern instruments and equipment use sensing devices.

Array sensors are a common type of sensing device. Noise-equivalent temperature difference (NETD) is one of the important factors affecting the sensing capability of array sensors, and it is related to packaging adaption. In general, in the process of manufacturing a sensing device, the stacked structure may have an uneven surface, which can easily cause poor adhesion between the upper and lower substrates, thereby affecting the vacuum degree of the package after bonding. Furthermore, the current packaging process is still relatively complex, with problems such as low process yield and high production costs.

Therefore, further improving the structural design of the sensing device and its manufacturing method, such as simplifying the manufacturing process or improving the yield, is still one of the current research topics in the industry.

### SUMMARY

In accordance with some embodiments of the present disclosure, a sensing substrate is provided. The sensing substrate includes a first substrate, a circuit layer, a planarization layer, a sensing unit and a first bonding layer. The circuit layer is disposed on the first substrate. The planarization layer is disposed on the circuit layer, and the planarization layer includes an opening. The sensing unit is disposed on the planarization layer, and the sensing unit is electrically connected to the circuit layer through the opening. The first bonding layer is disposed on the planarization layer.

In accordance with some other embodiments of the present disclosure, a sensing device is provided. The sensing device includes a sensing substrate and an optical substrate. The sensing device includes a first substrate, a circuit layer, a planarization layer, a sensing unit and a first bonding layer. The circuit layer is disposed on the first substrate. The planarization layer is disposed on the circuit layer, and the planarization layer includes an opening. The sensing unit is disposed on the planarization layer, and the sensing unit is electrically connected to the circuit layer through the opening. The first bonding layer is disposed on the planarization layer. The optical substrate includes a second substrate and a second bonding layer disposed on the second substrate. Furthermore, the optical substrate and the sensing substrate are bonded to each other through the first bonding layer and the second bonding layer.

In accordance with still some other embodiments of the present disclosure, a method for manufacturing a sensing device is provided. The method includes providing a first substrate. The method includes forming a circuit layer on the first substrate. The method includes forming a planarization layer on the circuit layer. The planarization layer includes a first opening. The method includes forming a sensing unit on the planarization layer. The sensing unit is electrically connected to the circuit layer through the first opening. The method includes forming a first bonding layer on the planarization layer.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A to 1E are cross-sectional diagrams of a sensing substrate during the intermediate stages of the manufacturing process in accordance with some embodiments of the present disclosure;

FIGS. 2A to 2E are cross-sectional diagrams of an optical substrate during the intermediate stages of the manufacturing process in accordance with some embodiments of the present disclosure;

FIG. 3 is a cross-sectional diagram of a sensing substrate and an optical substrate of a sensing device in accordance with some embodiments of the present disclosure;

FIG. 4 is a cross-sectional diagram of a sensing device in accordance with some embodiments of the present disclosure;

FIG. 5 is an equivalent circuit diagram of a sensing device in accordance with some embodiments of the present disclosure.

### DETAILED DESCRIPTION

The sensing substrate, the sensing device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make sure that an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, a sensing substrate is provided. The sensing substrate includes a sensing unit and a bonding layer disposed on a planarization layer, which can provide a relatively flat structural surface and can improve the adhesion during bonding, thereby improving the vacuum tightness of the packaging of the sensing device. The noise equivalent temperature difference (NETD) of the sensing device can be improved, and the sensing capability of the sensing device can be enhanced.

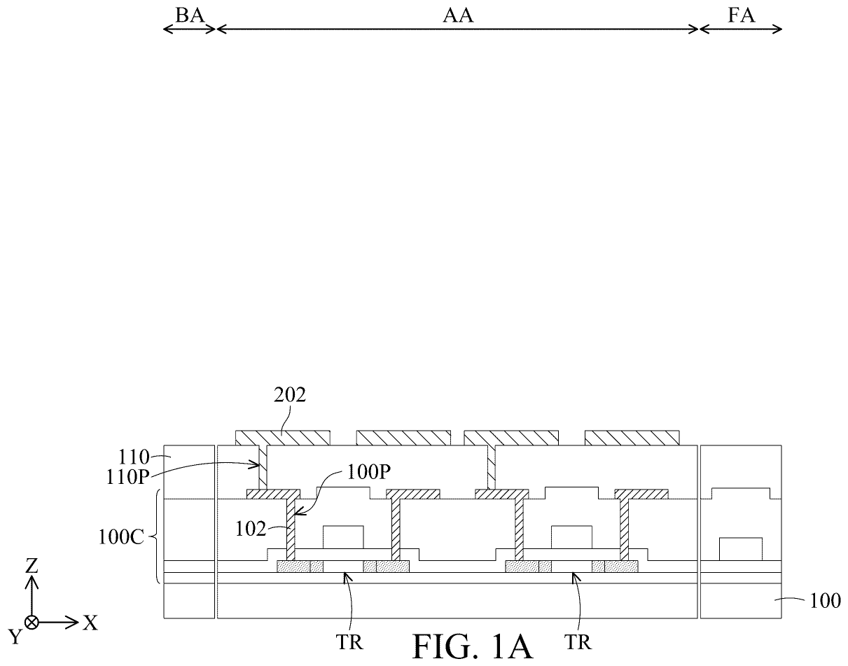

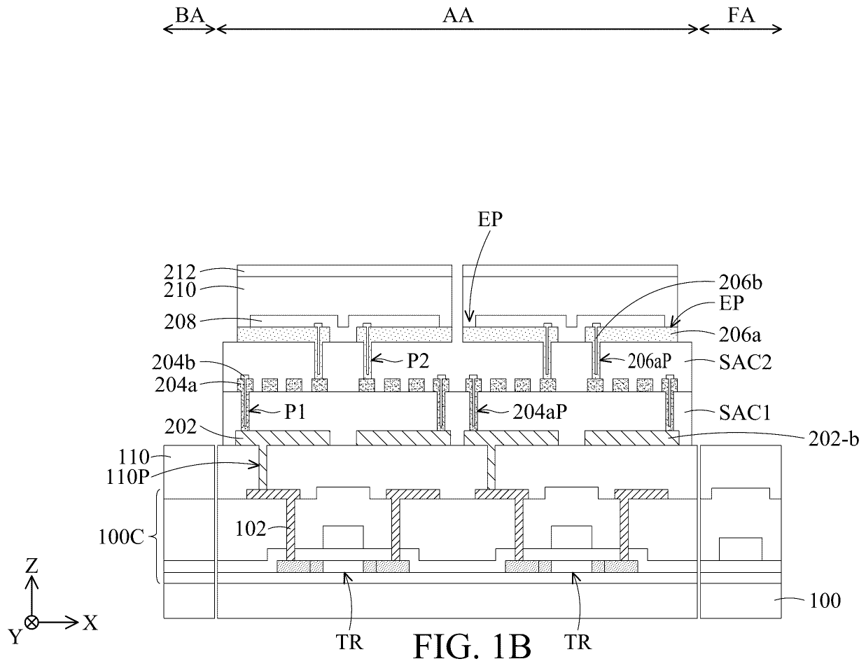

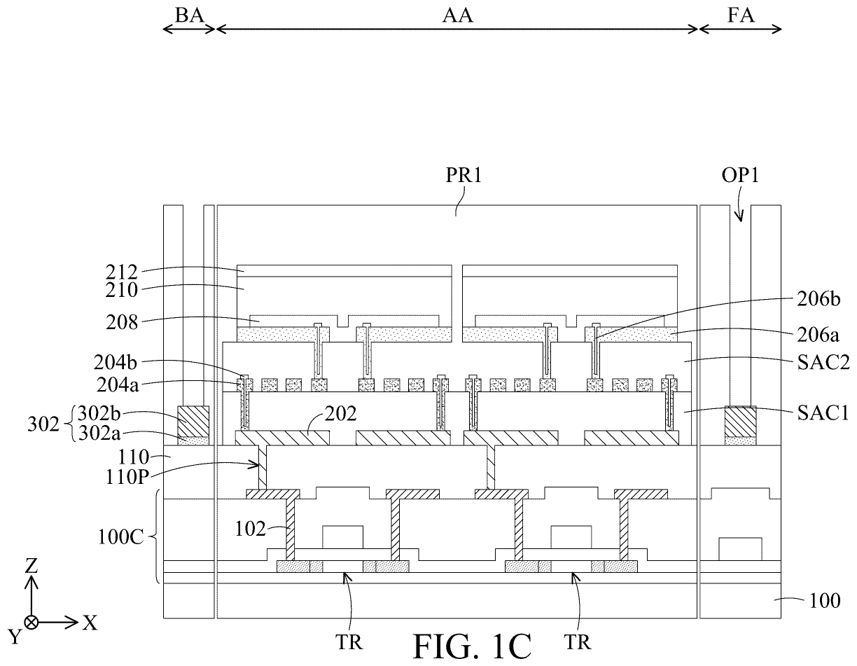

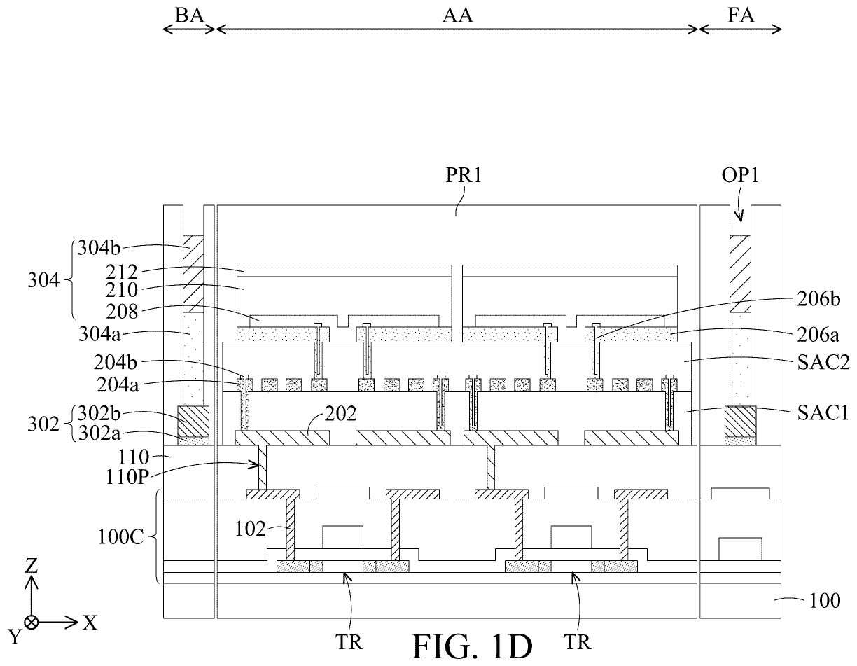

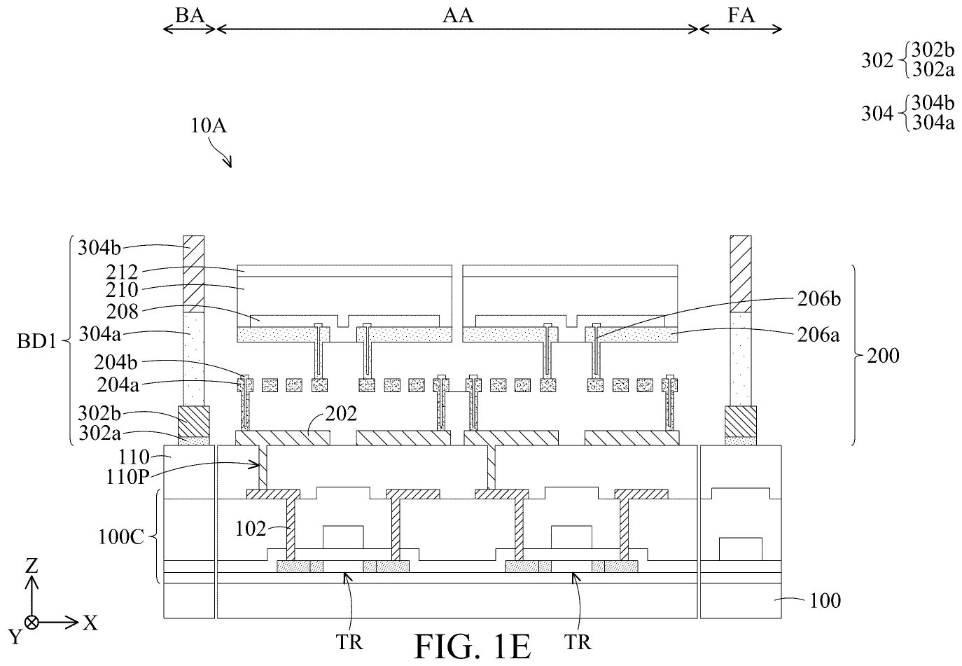

Please refer to FIGS. 1A to 1E, which are cross-sectional diagrams of a sensing substrate 10A during the intermediate stages of the manufacturing process in accordance with some embodiments of the present disclosure. It should be understood that, in accordance with some embodiments, additional operating steps may be provided before, during and/or after the manufacturing method of the sensing substrate 10A. In accordance with some embodiments, some of the described operating steps may be replaced or omitted. In accordance with some embodiments, the order of some of the operating steps is interchangeable. Furthermore, for clarity of explanation, some components of the sensing substrate 10A may be omitted in the figure, and only some components are schematically illustrated. In accordance with some embodiments, additional features may be added to the sensing substrate 10A described below. In accordance with some other embodiments, some features of the sensing substrate 10A described below may be replaced or omitted.

First, referring to FIG. 1A, a first substrate 100 is provided. The first substrate 100 may have areas corresponding to a peripheral area BA, an active area AA, and a fan-out area FA of the sensing device. In accordance with some embodiments, the first substrate 100 may include a flexible substrate, a rigid substrate, or a combination thereof, but it is not limited thereto. In accordance with some embodiments, the material of the first substrate 100 may include glass, quartz, sapphire, ceramic, polyimide (PI), polycarbonate (PC), polyethylene terephthalate (PET), polypropylene (PP), another suitable material or a combination thereof, but it is not limited thereto. Furthermore, in accordance with some embodiments, the first substrate 100 may include a metal-glass fiber composite plate or a metal-ceramic composite plate, but it is not limited thereto. In addition, the light transmittance of the first substrate 100 is not limited, that is, the first substrate 100 may be a transparent substrate, a semi-transparent substrate or an opaque substrate. Next, a circuit layer 100C is formed on the first substrate 100. In accordance with some embodiments, the circuit layer 100C may include a buffer layer (not labeled) and a thin-film transistor TR disposed on the buffer layer. The thin-film transistor TR may be located in the active area AA. The circuit layer 100C may include conductive components and signal lines electrically connected to the thin-film transistor TR, and insulating layers formed between conductive components, etc. In accordance with some embodiments, the signal line may include, for example, a current signal line, a voltage signal line, a high-frequency signal line, and a low-frequency signal line, and the signal line can transmit device operating voltage (VDD), common ground voltage (VSS), or the voltage of driving device end portion, but the present disclosure is not limited thereto.

The thin-film transistor TR may include a top gate thin-film transistor, a bottom gate thin-film transistor, a dual gate or double gate thin-film transistor, or a combination thereof. In accordance with some embodiments, the thin-film transistor TR may be further electrically connected to the capacitive element, but it is not limited thereto. The thin-film transistor TR may include at least one semiconductor layer and a gate electrode layer. The semiconductor layer may include doped regions with appropriate dopants and a channel region located between the two doped regions, and the doped regions may further include parts with different doping concentrations. Furthermore, the semiconductor layer may include amorphous silicon, low-temp polysilicon (LTPS), metal oxide, another suitable material, or a combination thereof, but it is not limited thereto. The metal oxide may include indium gallium zinc oxide (IGZO), indium zinc oxide (IZO), indium gallium oxide (IGO), indium gallium zinc tin oxide (IGZTO), another suitable material or a combination thereof, but it is not limited thereto. It should be understood that the number of thin-film transistors TR is not limited to that shown in the figure, and the sensing substrate 10A may have other suitable numbers or types of thin-film transistors according to different embodiments. As shown in FIG. 1A, the circuit layer 100C includes a conductive layer 102. The conductive layer 102 may serve as a contact for the source electrode or the drain electrode of the thin-film transistor TR so that the source electrode or the drain electrode of the thin-film transistor TR may be electrically connected to the subsequently formed sensing unit 200 (as shown in FIG. 1E).

Specifically, a portion of the gate dielectric layer and the dielectric layer in the circuit layer 100C may be removed through a patterning process to form an opening 100P, and then the conductive layer 102 may be formed in the opening 100P. In accordance with some embodiments, a portion of the gate dielectric layer and the dielectric layer may be removed through one or more photolithography processes and/or etching processes to form the opening 100P. In accordance with some embodiments, the photolithography process may include photoresist coating (such as spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

In accordance with some embodiments, the conductive layer 102 may include a metal material, a transparent conductive material, another suitable conductive material, or a combination thereof, but it is not limited thereto. The metal material may include, for example, copper (Cu), silver (Ag), gold (Au), tin (Sn), aluminum (Al), molybdenum (Mo), tungsten (W), chromium (Cr), nickel (Ni), platinum (Pt), titanium (Ti), alloys of the foregoing metals, another suitable material or a combination thereof, but it is not limited thereto. The transparent conductive material may include transparent conductive oxide (TCO), for example, may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material, or a combination thereof, but it is not limited thereto. In accordance with some embodiments, the conductive layer 102 may be formed by a chemical vapor deposition process, a physical vapor deposition process, an electroplating process, an electroless plating/electroless plating process, another suitable process, or a combination thereof. The chemical vapor deposition process may include, for example, low pressure chemical vapor deposition (LPCVD), low temperature chemical vapor deposition (LTCVD), rapid thermal chemical vapor deposition (RTCVD), plasma enhanced chemical vapor deposition (PECVD) or atomic layer deposition (ALD), etc., but it is not limited thereto. The physical vapor deposition process may include, for example, sputtering process, evaporation process, or pulsed laser deposition, etc., but it is not limited thereto.

Referring to FIG. 1A, a planarization layer 110 is formed on the circuit layer 100C, and the planarization layer 110 includes an opening 110P. The planarization layer 110 can provide a relatively flat structural surface for subsequently formed sensing unit 200 and first bonding layer BD1. In accordance with some embodiments, the planarization layer 110 may include an insulating material, and the insulating material may include an inorganic material or an organic material. In accordance with some embodiments, the inorganic material may include silicon nitride, silicon oxide, silicon oxynitride, aluminum oxide, another suitable material, or a combination thereof, but it is not limited thereto. In accordance with some embodiments, the insulating material may be formed on the circuit layer 100C through a chemical vapor deposition process, a coating process, a printing process, another suitable process, or a combination thereof. In addition, a planarization process may be performed on the insulating material to form the planarization layer 110 so that it has a substantially flat top surface. In accordance with some embodiments, the planarization process may include a chemical-mechanical polish (CMP) process, a grinding process, another suitable planarization process, or a combination thereof.

Furthermore, a portion of the planarization layer 110 may be removed through a patterning process to form the opening 110P, and the opening 110P may expose the conductive layer 102. In accordance with some embodiments, the patterning process may include one or more photolithography processes and/or etching processes.

Next, the conductive layer 202 is formed in the opening 110P. The conductive layer 202 may serve as a conductive element of the subsequently formed sensing unit 200, and the sensing unit 200 may be electrically connected to the circuit layer 100C through the opening 110P. In accordance with some embodiments, the material and manufacturing method of the conductive layer 202 may be the same as or similar to the aforementioned material and manufacturing method of the conductive layer 102, and thus will not be repeated here.

Referring to FIG. 1B, the sensing unit 200 is formed on the planarization layer 110. As mentioned above, the sensing unit 200 may be electrically connected to the circuit layer 100C through the opening 110P. Specifically, forming the sensing unit 200 on the planarization layer 110 may include the following steps.

First, a first sacrificial layer SAC1 is formed on the planarization layer 110, and the first sacrificial layer SAC1 also covers the conductive layer 202. In accordance with some embodiments, the material of the first sacrificial layer SAC1 may include an organic material, such as polyimide (PI), acrylic resin, SU-8 photoresist, parylene C, another suitable material or a combination thereof, but it is not limited thereto. In accordance with some embodiments, the first sacrificial layer SAC1 may be formed through a chemical vapor deposition process, a coating process, a printing process, another suitable process, or a combination thereof.

Furthermore, a portion of the first sacrificial layer SAC1 may be removed through a patterning process to form an opening P1, and the opening P1 may expose the conductive layer 202. In accordance with some embodiments, the patterning process may include one or more photolithography processes and/or etching processes.

Next, a supporting element 204a is formed on the first sacrificial layer SAC, and the supporting element 204a is also filled in the opening P1 of the first sacrificial layer SAC1. The supporting element 204a can support the sensing unit 200 and enhance the structural strength of the sensing unit 200. In accordance with some embodiments, the material of the supporting element 204a may include titanium nitride (TiN), titanium aluminum nitride (TiAl), titanium aluminum nitride (TiAlN), titanium aluminum oxide (TiAlO), aluminum titanium silicon (TiSiAl), tungsten Titanium (TiW), titanium tungsten nitride (TiWN), aluminum nitride (AlNx), another suitable material or a combination thereof, but it is not limited thereto. In accordance with some embodiments, the supporting element 204a may have a multi-layer structure. Furthermore, in accordance with some embodiments, the supporting element 204a may be formed by a chemical vapor deposition process, a physical vapor deposition process, a coating process, a printing process, another suitable process, or a combination thereof.

In addition, the supporting element 204a may be patterned through one or more photolithography processes and/or etching processes. In accordance with some embodiments, the supporting element 204a may have a ring-like structure. For example, in a top-view diagram, the supporting element 204a may have a plurality of bent portions or a loop shape, but it is not limited thereto. It should be noted that the supporting element 204a can reduce heat conduction, reduce heat energy dissipation of the sensing unit 200, and thereby improve the sensing capability. A portion of the supporting element 204a may be located in the opening P1 to form an opening 204aP, and the opening 204aP may be located within the opening P1.

Next, a fixing element 204b is formed in the opening 204aP. In accordance with some embodiments, the fixing element 204b may be partially formed on the supporting element 204a. The fixing element 204b can further enhance the structural strength of the supporting element 204a. In accordance with some embodiments, the material of the fixing element 204b may include molybdenum (Mo), molybdenum nitride (MoN), tungsten molybdenum (MoW), tungsten (W), another suitable material, or a combination thereof, but it is not limited thereto. In accordance with some embodiments, the fixing element 204b may be formed by a chemical vapor deposition process, a physical vapor deposition process, an electroplating process, an electroless plating/electroless plating process, another suitable process, or a combination thereof.

Next, a second sacrificial layer SAC2 is formed on the supporting element 204a, and the second sacrificial layer SAC2 also covers the first sacrificial layer SAC1 and the fixing element 204b. In accordance with some embodiments, the material and manufacturing method of the second sacrificial layer SAC2 may be the same as or similar to the aforementioned material and manufacturing method of the first sacrificial layer SAC1, and thus will not be repeated here.

Furthermore, a portion of the second sacrificial layer SAC2 may be removed through a patterning process to form an opening P2, and the opening P2 may expose the supporting element 204a. In accordance with some embodiments, the patterning process may include one or more photolithography processes and/or etching processes.

Next, an absorbing layer 206a is formed on the second sacrificial layer SAC2, and the absorbing layer 206a is also filled in the opening P2 of the second sacrificial layer SAC2. The absorbing layer 206a can absorb light within the wavelength range to be detected. For example, in accordance with some embodiments, the absorbing layer 206a can absorb infrared (IR), such as longwave infrared (LWIR), shortwave infrared (SWIR), middle wave infrared (MWIR) or far infrared (FIR). In accordance with some embodiments, the material of the absorbing layer 206a may include titanium (Ti), titanium nitride (TiN), platinum (Pt), gold (Au), nickel (Ni), niobium (Nb), another suitable material, or a combination thereof, but it is not limited thereto. In accordance with some embodiments, the absorbing layer 206 may be formed by a chemical vapor deposition process, a physical vapor deposition process, an electroplating process, an electroless plating/electroless plating process, another suitable process, or a combination thereof.

In addition, in accordance with some embodiments, a portion of the absorbing layer 206a is located in the opening P2 to form an opening 206aP, and the opening 206aP is located within the opening P2.

Next, a fixing element 206b is formed in the opening 206aP. In accordance with some embodiments, the fixing element 206b is partially formed on the absorbing layer 206a. The fixing element 206b can fix the absorbing layer 206a to the supporting element 204a. In accordance with some embodiments, the material and manufacturing method of the fixing element 206b may be the same as or similar to the aforementioned material and manufacturing method of the fixing element 204b, and thus will not be repeated here.

Next, an insulating layer 208 is formed on the absorbing layer 206a, and the insulating layer 208 also covers the second sacrificial layer SAC2 and the fixing element 206b. In accordance with some embodiments, the material of the insulating layer 208 may include silicon nitride (SiNx), silicon oxide (SiOx), silicon oxynitride (SiON), another suitable material, or a combination thereof, but it is not limited thereto. In accordance with some embodiments, the insulating layer 208 may be formed by a chemical vapor deposition process, a physical vapor deposition process, a coating process, a printing process, another suitable process, or a combination thereof.

Moreover, a portion of the insulating layer 208 may be removed through a patterning process to expose two end portions EP of the absorbing layer 206a. In accordance with some embodiments, the patterning process may include one or more photolithography processes and/or etching processes.

Next, a sensing layer 210 is formed on the insulating layer 208, and the sensing layer 210 is in contact with the two end portions EP of the absorbing layer 206a. The sensing layer 210 may have thermo-sensitive characteristics, and the two end portions of the sensing layer 210 may be connected to the absorbing layer 206a, thereby forming a resistor structure. Specifically, one end portion of the resistor structure may be electrically connected to the conductive layer 202 and the conductive layer 102 through the supporting element 204a, and then electrically connected to the thin-film transistor TR of the circuit layer 100C, and the other end portion of the resistor structure may be electrically connected to the conductive layer 202 (labeled as 202-b for convenience of explanation) connected to the bias signal line. In accordance with some embodiments, the material of the sensing layer 210 may include amorphous silicon (a-Si), vanadium oxide (VOx), yttrium barium copper oxide (YBaCuO), germanium silicon oxide (GeSiO), germanium silicon (SiGe), bismuth lanthanum strontium manganese oxide (BiLaSrMnO), another suitable material or a combination thereof, but it is not limited thereto. In accordance with some embodiments, the sensing layer 210 may be formed by a chemical vapor deposition process, a physical vapor deposition process, a coating process, a printing process, another suitable process, or a combination thereof.

Next, an insulating layer 212 is formed on the sensing layer 210. In accordance with some embodiments, the material and manufacturing method of the insulating layer 212 may be the same as or similar to the aforementioned material and manufacturing method of the insulating layer 208, and thus will not be repeated here.

Referring to FIG. 1C, FIG. 1D and FIG. 1E, a first bonding layer BD1 is formed on the planarization layer 110. First, a first seed layer 302 is formed on the planarization layer 110. Specifically, the first seed layer 302 may be formed on the planarization layer 110 located in the peripheral area BA and the fan-out area FA. In accordance with some embodiments, the first seed layer 302 may have a multi-layer structure, such as having a sub-layer 302a and a sub-layer 302b disposed on the sub-layer 302a. In accordance with some embodiments, the material of the sub-layer 302a may include molybdenum (Mo), titanium (Ti) or another suitable material, but it is not limited thereto. In accordance with some embodiments, the material of the sub-layer 302b may include copper (Cu) or another suitable material, but it is not limited thereto. It should be understood that although the first seed layer 302 shown in the drawings has two sub-layers, the present disclosure is not limited thereto. In accordance with some embodiments, the first seed layer 302 may have other suitable numbers or types of sub-layers. In accordance with some embodiments, the first seed layer 302 may include a molybdenum/copper composite layer, a titanium/copper composite layer, a molybdenum/aluminum composite layer, or a titanium/aluminum composite layer. In addition to being a seed layer, the titanium/copper composite layer can also be used as a getter to absorb outgassing. In accordance with some embodiments, the first seed layer 302 may be formed by a chemical vapor deposition process, a physical vapor deposition process, an electroplating process, an electroless plating/electroless plating process, another suitable process, or a combination thereof.

Next, a first protective layer PR1 is formed on the first seed layer 302. Specifically, the first protective layer PR1 may be formed on the peripheral area BA, the active area AA and the fan-out area FA, and the first protective layer PR1 also covers the components of the sensing unit 200 formed above. In accordance with some embodiments, the material of the first protective layer PR1 may include a photoresist material, but it is not limited thereto. In accordance with some embodiments, the first protective layer PR1 may be formed by a chemical vapor deposition process, a physical vapor deposition process, a coating process, a printing process, another suitable process, or a combination thereof.

Furthermore, a portion of the first protective layer PR1 may be removed through a patterning process to form an opening OP1, and the opening OP1 may expose the first seed layer 302. Specifically, the opening OP1 may expose a portion of the top surface of the upper sub-layer 302b of the first seed layer 302. In accordance with some embodiments, the patterning process may include one or more photolithography processes and/or etching processes.

Next, a first metal layer 304 is formed in the opening OP1, and the first metal layer 304 is located on the first seed layer 302. At this stage, the first bonding layer BD1 is substantially completed. In accordance with some embodiments, the first metal layer 304 may have a multi-layer structure, such as having a sub-layer 304a and a sub-layer 304b disposed on the sub-layer 304a. In accordance with some embodiments, the material of the sub-layer 304a may include copper (Cu) or another suitable material, but it is not limited thereto. In accordance with some embodiments, the material of the sub-layer 304b may include tin (Sn) or another suitable material, but it is not limited thereto. It should be understood that although the first metal layer 304 shown in the drawings has two sub-layers, the present disclosure is not limited thereto. In accordance with some embodiments, the first metal layer 304 may have other suitable numbers or types of sub-layers. In accordance with some embodiments, the first metal layer 304 may include a tin/copper composite layer, a tin/gold/nickel/copper composite layer, a tin/gold/nickel composite layer, a gold/nickel composite layer, or a gold/nickel/copper composite layer. In accordance with some embodiments, the first metal layer 304 may be formed by a chemical vapor deposition process, a physical vapor deposition process, an electroplating process, an electroless plating/electroless plating process, another suitable process, or a combination thereof.

Next, referring to FIG. 1E, the first protective layer PR1 is removed to expose the first bonding layer BD1. It should be noted that the step of removing the first protective layer PR1 may also remove the first sacrificial layer SAC1 and the second sacrificial layer SAC2 at the same time to expose the sensing unit 200. After the first sacrificial layer SAC1 and the second sacrificial layer SAC2 are removed, the sensing unit 200 and the sensing substrate 10A are substantially completed. In accordance with some embodiments, the organic materials may be removed by a plasma etching process, for example, the first protective layer PR1, the first sacrificial layer SAC1 and the second sacrificial layer SAC2 may be removed, but it is not limited thereto.

Based on the above, the step of removing the first sacrificial layer SAC1 and the second sacrificial layer SAC2 is performed after the step of forming the first bonding layer BD1 on the planarization layer 110, thereby protecting the metal wirings in the sensing unit 200 and reducing damage to metal wirings caused by the etching process.

As shown in FIG. 1E, the formed sensing substrate 10A includes a first substrate 100, a circuit layer 100C, a planarization layer 110, a sensing unit 200 and a first bonding layer BD1. The circuit layer 100C is disposed on the first substrate 100. The planarization layer 110 is disposed on the circuit layer 100C, and the planarization layer 110 includes an opening 110P. The sensing unit 200 is disposed on the planarization layer 110, and the sensing unit 200 is electrically connected to the circuit layer 100C through the opening 110P. The first bonding layer BD1 is disposed on the planarization layer 110.

In accordance with some embodiments, the sensing unit 200 may include an absorbing layer 206a, an insulating layer 208, an insulating layer 212 and a sensing layer 210. The insulating layer 208 and the insulating layer 212 may be disposed on the absorbing layer 206a. The sensing layer 210 may be disposed between the insulating layer 208 and the insulating layer 212. In accordance with some embodiments, the sensing unit 200 may further include a supporting element 204a, and the supporting element 204a may be disposed between the planarization layer 110 and the absorbing layer 206a. In accordance with some embodiments, the sensing unit 200 may further include a fixing element 204b, and the fixing element 204b may be disposed in an opening 204aP of the supporting element. Furthermore, in accordance with some embodiments, the sensing unit 200 may further include a fixing element 206b, and the fixing element 206b may be disposed in an opening 206aP of the absorbing layer 206a.

In accordance with some embodiments, the first bonding layer BD1 may surround the sensing unit 200. As described above, in accordance with some embodiments, the supporting element 204a may have a ring-like structure. For example, in a top-view diagram, the supporting element 204a may have a plurality of bent portions or a loop shape, but it is not limited thereto. In accordance with some embodiments, the first bonding layer BD1 may include a first seed layer 302 and a first metal layer 304 disposed on the first seed layer 302. In accordance with some embodiments, the first seed layer 302 may include a molybdenum/copper composite layer, a titanium/copper composite layer, a molybdenum/aluminum composite layer, or a titanium/aluminum composite layer. In accordance with some embodiments, the first metal layer 304 may include a tin/copper composite layer, a tin/gold/nickel/copper composite layer, a tin/gold/nickel composite layer, a gold/nickel composite layer, or a gold/nickel/copper composite layer.

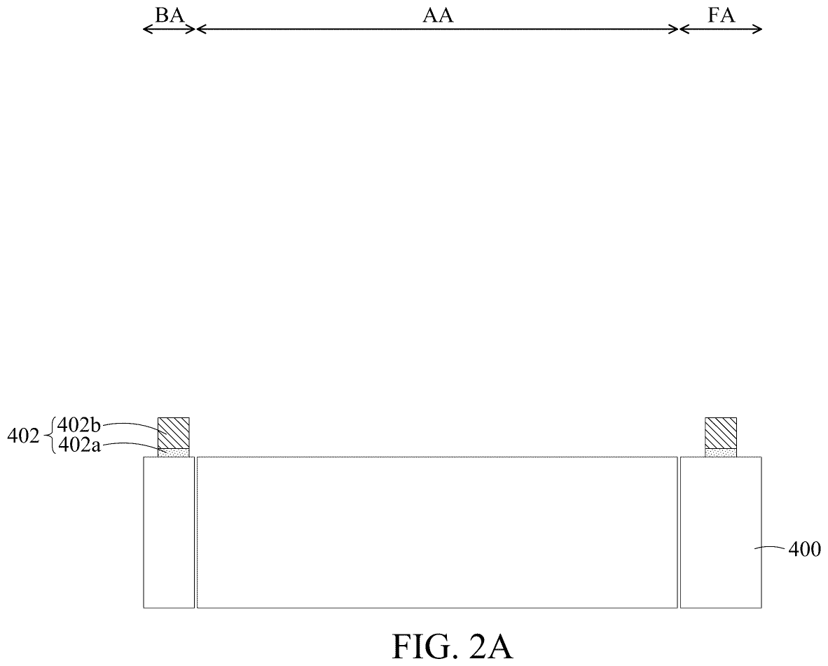

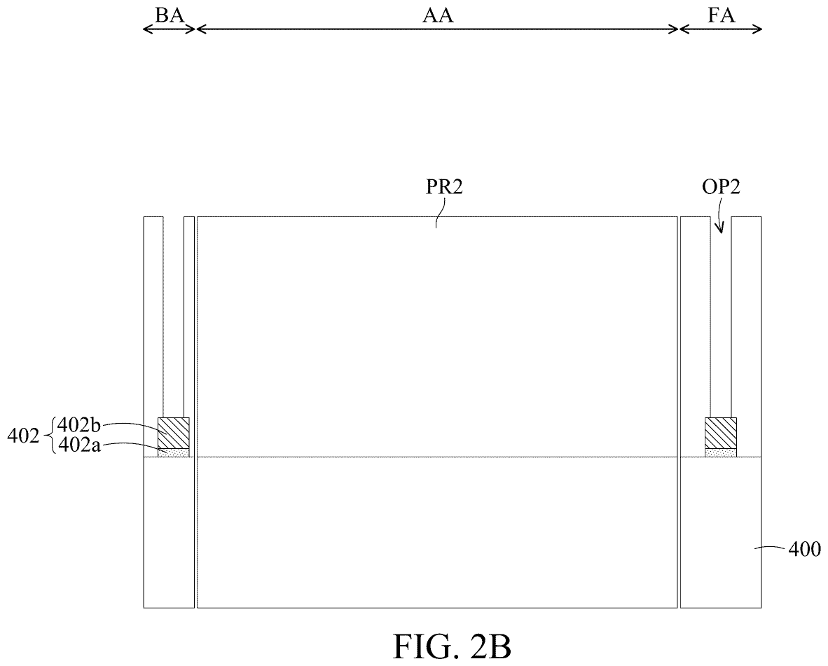

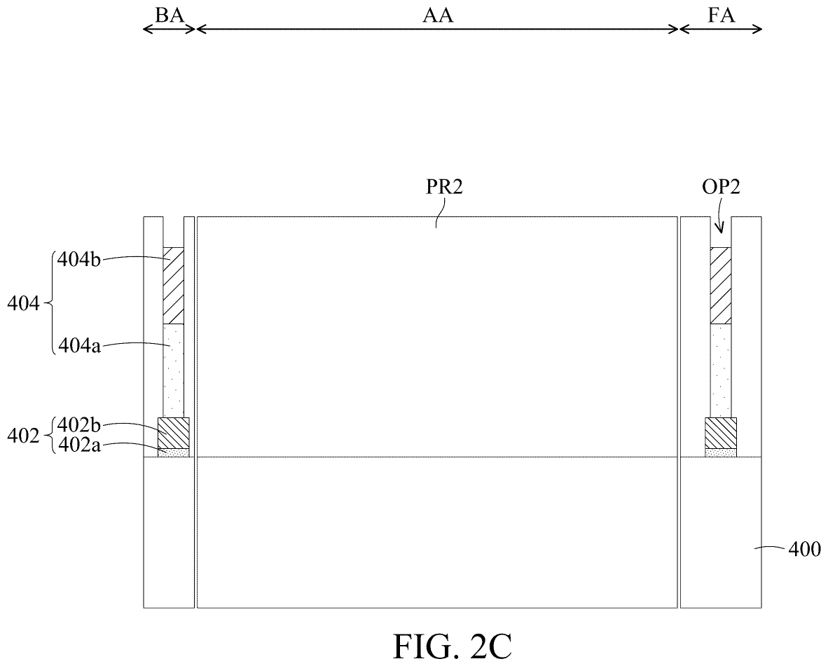

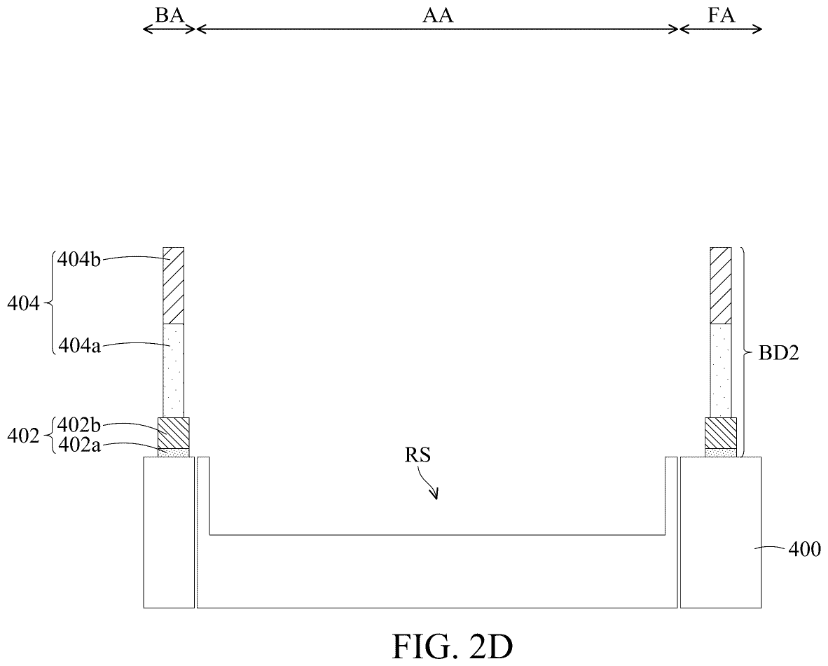

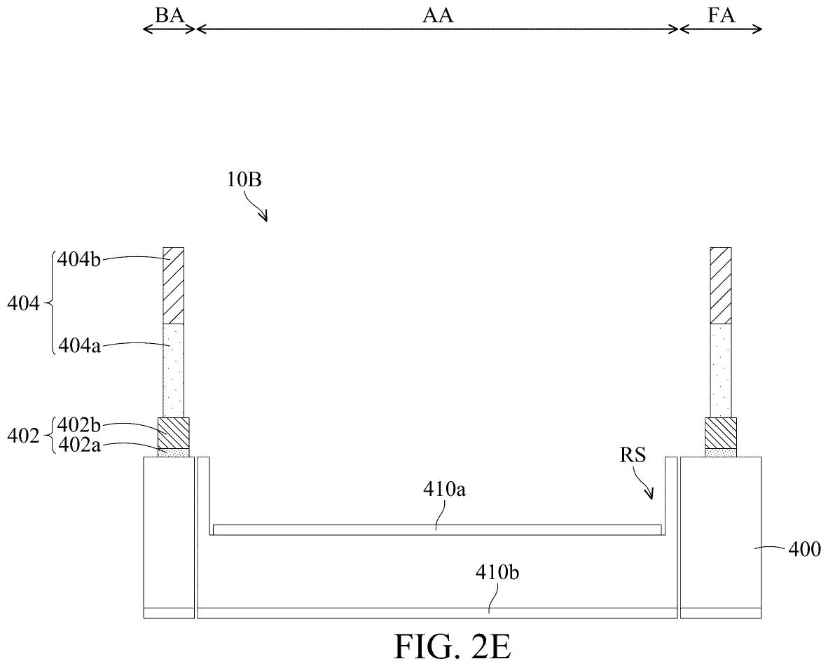

It should be noted that the aforementioned sensing unit 200 and the first bonding layer BD1 are located on the same side of the planarization layer 110, which can provide a relatively flat structural surface and improve the connection between the sensing substrate 10A and the opposite optical substrate 10B (as shown in FIG. 2E) during bonding, thereby improving the vacuum tightness of the packaging of the sensing device.

Please refer to FIGS. 2A to 2E, which are cross-sectional diagrams of an optical substrate 10B during the intermediate stages of the manufacturing process in accordance with some embodiments of the present disclosure. It should be understood that, in accordance with some embodiments, additional operating steps may be provided before, during, and/or after the manufacturing method of the optical substrate 10B. In accordance with some embodiments, some of the described operating steps may be replaced or omitted. In accordance with some embodiments, the order of some of the operating steps is interchangeable. Furthermore, for clarity of explanation, some components of the optical substrate 10B may be omitted in the figure, and only some components are schematically illustrated. In accordance with some embodiments, additional features may be added to the optical substrate 10B described below. In accordance with some other embodiments, some features of the optical substrate 10B described below may be replaced or omitted.

First, referring to FIG. 2A, a second substrate 400 is provided. The second substrate 400 can serve as a cover plate. In accordance with some embodiments, the second substrate 400 may have the function of filtering a specific waveband. For example, the second substrate 400 may filter out light outside the wavelength range to be detected. In accordance with some embodiments, the material of the second substrate 400 may include silicon (Si), germanium (Ge), chalcogenide glass, gallium arsenide (GaAs), another suitable material, or a combination thereof, but it is not limited thereto. In accordance with some embodiments, the second substrate 400 may further include an optical coating (not illustrated) disposed on its surface. The material of the optical coating may include germanium (Ge), zinc sulfide (ZnS), zinc selenide (ZnSe), magnesium fluoride (MgF₂), beryllium fluoride (BeF₂), potassium chloride (KCl), arsenic sulfide (As₂S₃), another suitable material or a combination thereof, but it is not limited thereto. Then, a second bonding layer BD2 is formed on the second substrate 400. First, as shown in FIG. 2A, a second seed layer 402 is formed on the second substrate 400. Specifically, the second seed layer 402 may be formed on the peripheral area BA and the fan-out area FA of the second substrate 400. In accordance with some embodiments, the second seed layer 402 may have a multi-layer structure, such as having a sub-layer 402a and a sub-layer 402b disposed on the sub-layer 402a. In accordance with some embodiments, the material of the sub-layer 402a may include molybdenum (Mo), titanium (Ti) or another suitable material, but it is not limited thereto. In accordance with some embodiments, the material of the sub-layer 402b may include copper (Cu) or another suitable material, but it is not limited thereto. It should be understood that although the second seed layer 402 illustrated in the drawings has two sub-layers, the present disclosure is not limited thereto. In accordance with some embodiments, the second seed layer 402 may have other suitable numbers or types of sub-layers. In accordance with some embodiments, the second seed layer 402 may include a molybdenum/copper composite layer or a titanium/copper composite layer. In addition to being a seed layer, the titanium/copper composite layer can also be used as a getter to absorb outgassing. In accordance with some embodiments, the second seed layer 402 may be formed by a chemical vapor deposition process, a physical vapor deposition process, an electroplating process, an electroless plating/electroless plating process, another suitable process, or a combination thereof.

Next, referring to FIG. 2B, a second protective layer PR2 is formed on the second seed layer 402. Specifically, the second protective layer PR2 may be formed on the peripheral area BA, the active area AA and the fan-out area FA. In accordance with some embodiments, the material and manufacturing method of the second protective layer PR2 may be the same as or similar to the aforementioned material and manufacturing method of the first protective layer PR1, and thus will not be repeated here.

Furthermore, a portion of the second protective layer PR2 may be removed through a patterning process to form an opening OP2, and the opening OP2 may expose the second seed layer 402. Specifically, the opening OP2 may expose a portion of the top surface of the upper sub-layer 402b of the second seed layer 402. In accordance with some embodiments, the patterning process may include one or more photolithography processes and/or etching processes.

Next, referring to FIG. 2C, a second metal layer 404 is formed in the opening OP2, and the second metal layer 404 is located on the second seed layer 402. In accordance with some embodiments, the second metal layer 404 may have a multi-layer structure, such as having a sub-layer 404a and a sub-layer 404b disposed on the sub-layer 404a. In accordance with some embodiments, the material of the sub-layer 404a may include copper (Cu) or another suitable material, but it is not limited thereto. In accordance with some embodiments, the material of the sub-layer 404b may include tin (Sn) or another suitable material, but it is not limited thereto. It should be understood that although the second metal layer 404 shown in the drawings has two sub-layers, the present disclosure is not limited thereto. In accordance with some embodiments, the second metal layer 404 may have other suitable numbers or types of sub-layers. In accordance with some embodiments, the second metal layer 404 may include a tin/copper composite layer, a tin/gold/nickel/copper composite layer, or a gold/nickel/copper composite layer. In accordance with some embodiments, the second metal layer 404 may be formed by a chemical vapor deposition process, a physical vapor deposition process, an electroplating process, an electroless plating/electroless plating process, another suitable process, or a combination thereof.

Next, referring to FIG. 2D, the second protective layer PR2 is removed to expose the second bonding layer BD2. It should be noted that the step of removing the second protective layer PR2 may also remove a portion of the second substrate 400 to form a recess RS in the second substrate 400. In accordance with some embodiments, the second protective layer PR2 and a portion of the second substrate 400 may be removed through a plasma etching process, but it is not limited thereto.

Referring to FIG. 2D, after removing the second protective layer PR2, an anti-reflective layer 410a and an anti-reflective layer 410b are formed on both sides of the second substrate 400, and the anti-reflective layer 410a is disposed in the recess RS. The anti-reflective layer 410a and the anti-reflective layer 410b can reduce the reflectivity and increase the light transmittance. In accordance with some embodiments, the materials of the anti-reflective layer 410a and the anti-reflective layer 410b may include germanium (Ge), zinc sulfide (ZnS), zinc selenide (ZnSe), magnesium fluoride (MgF₂), beryllium fluoride (BeF₂), potassium chloride, arsenic sulfide (As₂S₃), another suitable material or a combination thereof, but it is not limited thereto. Furthermore, the material of the anti-reflective layer 410a may be the same as or different from the material of the anti-reflective layer 410b. In accordance with some embodiments, the anti-reflective layer 410a and the anti-reflective layer 410b may be formed by a chemical vapor deposition process, a physical vapor deposition process, an electroplating process, an electroless plating/electroless plating process, another suitable process, or a combination thereof, but it is not limited thereto. At this stage, the optical substrate 10B is substantially completed.

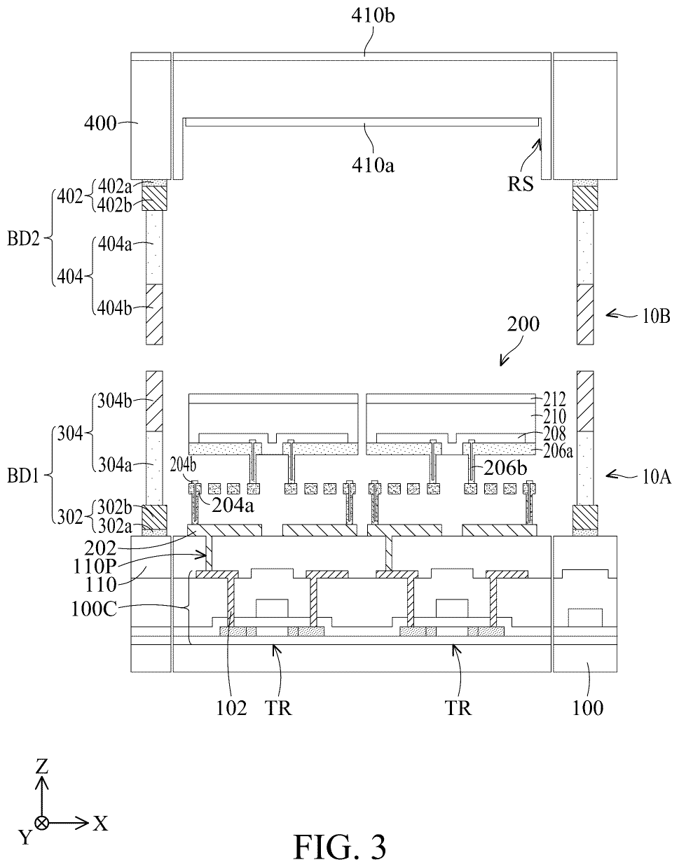

Please refer to FIG. 3, which is a cross-sectional diagram of the sensing substrate 10A and the optical substrate 10B of a sensing device in accordance with some embodiments of the present disclosure. In detail, FIG. 3 shows a schematic diagram of the sensing substrate 10A and the optical substrate 10B before they are joined together. As shown in FIG. 3, the first bonding layer BD1 of the sensing substrate 10A and the second bonding layer BD2 of the optical substrate 10B are aligned. More specifically, the first metal layer 304 of the first bonding layer BD1 and the second metal layer 404 of the second bonding layer BD2 may be aligned so that the sensing unit 200 faces the recess RS.

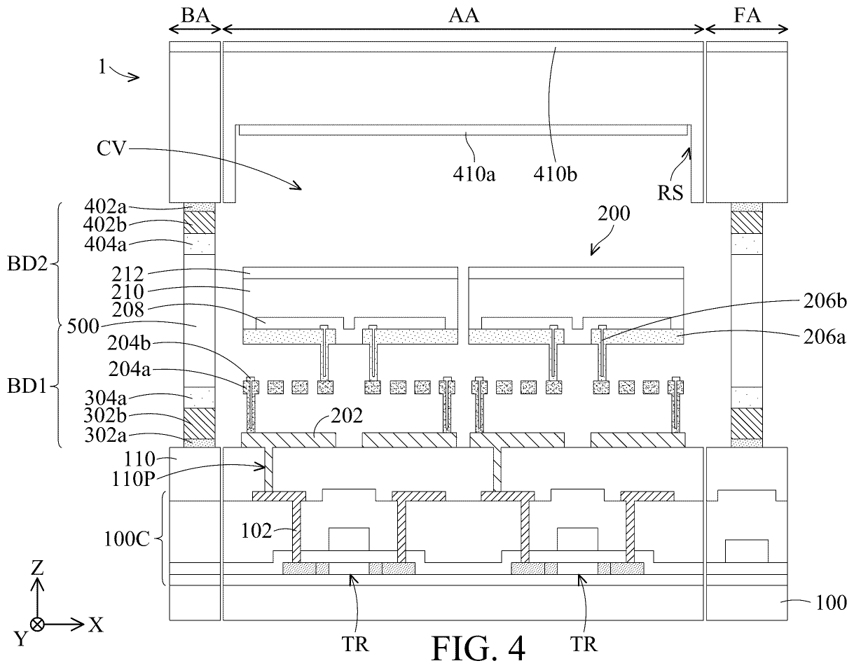

Please refer to FIG. 4, which is a cross-sectional diagram of a sensing device 1 in accordance with some embodiments of the present disclosure. In detail, FIG. 4 shows a schematic diagram of the sensing substrate 10A and the optical substrate 10B after they are paired and bonded. In accordance with some embodiments, the first bonding layer BD1 and the second bonding layer BD2 may be melted through a bonding process, so that the sensing substrate 10A and the optical substrate 10B are bonded to each other. The first metal layer 304 of the first bonding layer BD1 and the second metal layer 404 of the second bonding layer BD2 undergo a melting reaction to form a bonding structure 500. In accordance with some embodiments, the bonding structure 500 may include Cu₃Sn, Au₅Sn, gold (Au), another suitable material, or a combination thereof, but it is not limited thereto. The bonding process may include heating, pressure, lighting or a combination thereof. In accordance with some embodiments, the temperature of the bonding process may be between 100° C. and 500° C., or between 150° C. and 400° C., or between 200° C. and 300° C.

As shown in FIG. 4, the formed sensing device 1 includes a sensing substrate 10A and an optical substrate 10B. The sensing substrate 10A includes a first substrate 100, a circuit layer 100C, a planarization layer 110, a sensing unit 200 and a first bonding layer BD1. The circuit layer 100C is disposed on the first substrate 100. The planarization layer 110 is disposed on the circuit layer 100C, and the planarization layer 110 includes an opening 110P. The sensing unit 200 is disposed on the planarization layer 110, and the sensing unit 200 is electrically connected to the circuit layer 100C through the opening 110P. The first bonding layer BD1 is disposed on the planarization layer 110.

The optical substrate 10B includes a second substrate 400 and a second bonding layer BD2 disposed on the second substrate 400. In accordance with some embodiments, the optical substrate 10B includes an anti-reflective layer 410a and an anti-reflective layer 410b, and the anti-reflective layer 410a and the anti-reflective layer 410b are disposed on the surface of the second substrate 400. Furthermore, the optical substrate 10B includes a recess RS, and the recess RS overlaps with the sensing unit 200. In detail, the recess RS overlaps the sensing unit 200 in the normal direction of the second substrate 400 (e.g., the Z direction in the figure).

In addition, the optical substrate 10B and the sensing substrate 10A are bonded to each other through the first bonding layer BD1 and the second bonding layer BD2. In accordance with some embodiments, the first bonding layer BD1 and the second bonding layer BD2 undergo a melting reaction to form a bonding structure 500. The bonding structure 500 includes Cu₃Sn, Au₅Sn, gold (Au), another suitable material, or a combination thereof, but it is not limited thereto. In detail, the first metal layer 304 of the first bonding layer BD1 and the second metal layer 404 of the second bonding layer BD2 may undergo a melting reaction to form the bonding structure 500. Furthermore, in accordance with some embodiments, the first bonding layer BD1 and the second bonding layer BD2 are bonded to each other to form a cavity CV in the sensing device 1. As described above, the configuration of the sensing substrate 10A can improve the adhesion during bonding, improve the vacuum tightness of the packaging of the sensing device 1, thereby improving the sensing sensitivity of the sensing device 1 or improving the overall performance of the sensing device 1.

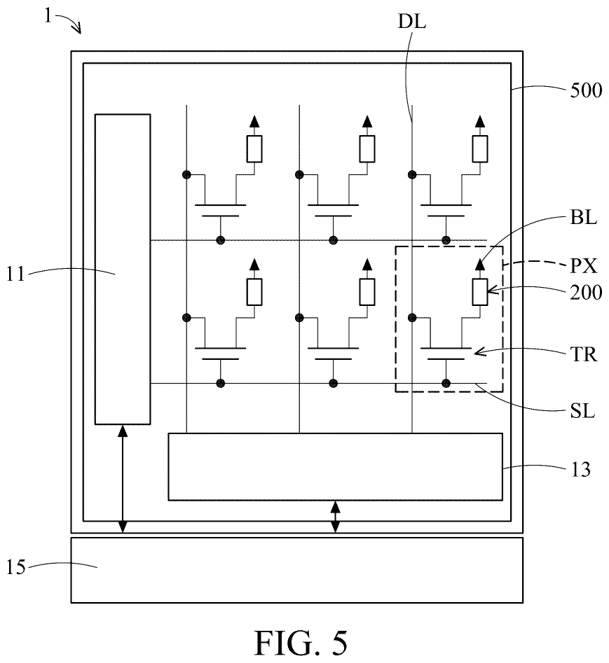

Please refer to FIG. 5, which is an equivalent circuit diagram of the sensing device 1 in accordance with some embodiments of the present disclosure. As shown in FIG. 5, the sensing device 1 has a sensing array, the sensing array has a plurality of sensing pixels PX, and the bonding structure 500 is disposed around the sensing array. In accordance with some embodiments, the sensing pixel PX may include the thin-film transistor TR as a driving element and the sensing unit 200. The thin-film transistor TR may be electrically connected to a scan line SL, a data line DL and the sensing unit 200. One end of the sensing unit 200 may be electrically connected to the thin-film transistor TR, and the other end may be electrically connected to a bias signal line BL. In accordance with some embodiments, the scan line SL may be electrically connected to a row driver 11. Furthermore, in accordance with some embodiments, the data line DL may be electrically connected to a readout driver 13. The row driver 11 may be further electrically connected to an integrated circuit (IC) element 15, and the readout driver 13 may be further electrically connected to the integrated circuit element 15 so as to read sensing signals through the integrated circuit element 15.

To summarize the above, in accordance with the embodiments of the present disclosure, the sensing substrate provided can provide a relatively flat structural surface, which can improve the adhesion when bonded with the optical substrate, thereby improving the vacuum tightness of the packaging of the sensing device. Therefore, the sensing sensitivity of the sensing device can be improved, or the overall performance of the sensing device can be enhanced.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A sensing substrate, comprising:
a first substrate;
a circuit layer disposed on the first substrate;
a planarization layer disposed on the circuit layer, wherein the planarization layer comprises an opening;
a sensing unit disposed on the planarization layer, wherein the sensing unit is electrically connected to the circuit layer through the opening; and
a first bonding layer disposed on the planarization layer.

2. The sensing substrate as claimed in claim 1, wherein the sensing unit and the first bonding layer are located on the same side of the planarization layer.

3. The sensing substrate as claimed in claim 1, wherein the sensing unit comprises:
an absorbing layer;
a first insulating layer and a second insulating layer disposed on the absorbing layer; and
a sensing layer disposed between the first insulating layer and the second insulating layer.

4. The sensing substrate as claimed in claim 3, wherein the sensing unit further comprises a supporting element disposed between the planarization layer and the absorbing layer.

5. The sensing substrate as claimed in claim 4, wherein the sensing unit further comprises a fixing element disposed in an opening of the supporting element.

6. The sensing substrate as claimed in claim 1, wherein the first bonding layer surrounds the sensing unit.

7. The sensing substrate as claimed in claim 1, wherein the first bonding layer comprises a first seed layer and a first metal layer disposed on the first seed layer.

8. The sensing substrate as claimed in claim 7, wherein the first seed layer comprises a molybdenum/copper composite layer, a titanium/copper composite layer, a molybdenum/aluminum composite layer or a titanium/aluminum composite layer.

9. The sensing substrate as claimed in claim 7, wherein the first metal layer comprises a tin/copper composite layer, a tin/gold/nickel/copper composite layer, a tin/gold/nickel composite layer, a gold/nickel composite layer or a gold/nickel/copper composite layer.

10. A sensing device, comprising:
a sensing substrate, comprising:
a first substrate;
a circuit layer disposed on the first substrate;
a planarization layer disposed on the circuit layer, wherein the planarization layer comprises an opening;
a sensing unit disposed on the planarization layer, wherein the sensing unit is electrically connected to the circuit layer through the opening; and
a first bonding layer disposed on the planarization layer; and
an optical substrate comprising a second substrate and a second bonding layer disposed on the second substrate;
wherein the optical substrate and the sensing substrate are bonded to each other through the first bonding layer and the second bonding layer.

11. The sensing device as claimed in claim 10, wherein the first bonding layer and the second bonding layer undergo a melting reaction to form a bonding structure, and the bonding structure comprises Cu₃Sn, Au₅Sn or gold.

12. The sensing device as claimed in claim 10, wherein the optical substrate further comprises an anti-reflective layer, and the anti-reflective layer is disposed on a surface of the second substrate.

13. The sensing device as claimed in claim 10, wherein the optical substrate comprises a recess and the recess overlaps the sensing unit.

14. The sensing device as claimed in claim 10, wherein the first bonding layer and the second bonding layer are bonded to each other to form a cavity in the sensing device.

15. A method of manufacturing a sensing device, comprising:
providing a sensing substrate, comprising:
providing a first substrate;
forming a circuit layer on the first substrate;
forming a planarization layer on the circuit layer, wherein the planarization layer comprises a first opening;
forming a sensing unit on the planarization layer, wherein the sensing unit is electrically connected to the circuit layer through the first opening; and
forming a first bonding layer on the planarization layer.

16. The method of manufacturing a sensing device as claimed in claim 15, wherein the step of forming the sensing unit on the planarization layer comprises:
forming a first sacrificial layer on the planarization layer;
forming a supporting element on the first sacrificial layer;
forming a second sacrificial layer on the supporting element;
forming an absorbing layer on the second sacrificial layer;
forming a first insulating layer on the absorbing layer;
forming a sensing layer on the first insulating layer; and
forming a second insulating layer on the sensing layer.

17. The method of manufacturing a sensing device as claimed in claim 16, wherein the step of forming the sensing unit on the planarization layer further comprises removing the first sacrificial layer and the second sacrificial layer, and the step of removing the first sacrificial layer and the second sacrificial layer is performed after the step of forming the first bonding layer on the planarization layer.

18. The method of manufacturing a sensing device as claimed in claim 15, wherein the step of forming the first bonding layer on the planarization layer comprises:
forming a first seed layer on the planarization layer;
forming a protective layer on the first seed layer;
removing a portion of the protective layer to form a second opening, wherein the second opening exposes the first seed layer;
forming a first metal layer in the second opening; and
removing the protective layer.

19. The method of manufacturing a sensing device as claimed in claim 15, further comprising:
providing an optical substrate, comprising:
providing a second substrate; and
forming a second bonding layer on the second substrate.

20. The method of manufacturing a sensing device as claimed in claim 19. further comprising melting the first bonding layer and the second bonding layer through a bonding process to bond the sensing substrate to the optical substrate.
